(19) United States
(12) Patent Application Publication
(10) Pub. No.: US 2010/0120247 A1
(43) Pub. Date: May 13, 2010

(54) METHOD OF FORMING FINE PATTERNS USING MULTIPLE SPACER PATTERNS

(75) Inventor: Hyungmoo Park, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/560,067

(22) Filed: Sep. 15, 2009

(30) Foreign Application Priority Data
Nov. 11, 2008 (KR) 10-2008-0111395

(51) Int. Cl. H01L 21/308; H01L 21/304

(52) U.S. Cl. 438/691; 438/696; 257/E21.231; 257/E21.237

(57) ABSTRACT

Fine patterns are formed by forming an etch-target layer on a substrate; forming support patterns on the etch-target layer; forming first spacer patterns on sidewalls of the support patterns; forming second spacer patterns coming in contact with the first spacer patterns; removing the support patterns; and etching the etch-target layer by using the first spacer patterns and the second spacer patterns as an etch mask.

### CROSS-REFERENCE TO RELATED APPLICATION

This U.S. nonprovisional patent application claims priority under 35 U.S.C. §119 of Korean Patent Application 10-2008-0111395, filed on Nov. 11, 2008, the entire contents of which are hereby incorporated by reference.

### BACKGROUND

The present invention relates to methods of forming patterns on a microelectronic substrate, which can be used to form fine patterns thereon.

Microelectronic devices such as integrated circuits are widely used in many consumer, commercial and other applications. As the integration density of microelectronic devices continues to increase, it may be desirable to form increasingly finer patterns on the microelectronic substrates.

Many patterns can be formed by performing photolithography. The photolithography may include performing exposure, development, and etching processes, after applying a photoresist on a material layer. As the microelectronic devices have been microminiaturized, the width of patterns and/or the distance between the patterns have become gradually finer. However, the width of pattern and/or the distance between the patterns may be limited by the photolithography due to various restrictions thereof.

### SUMMARY

Various embodiments of the present invention can provide methods of forming fine patterns. In some embodiments, the methods include forming an etch-target layer on a substrate; forming support patterns on the etch-target layer; forming first spacer patterns on sidewalls of the support patterns; forming second spacer patterns coming in contact with the first spacer patterns; removing the support patterns; and etching the etch-target layer by using the first spacer patterns and the second spacer patterns as an etch mask.

In other embodiments, the forming of the second spacer patterns and the removing of the support patterns may include forming a mold layer on the substrate having the support patterns and the first spacer patterns; polishing the mold layer until the support patterns are exposed; exposing one sidewall of the first spacer by removing the exposed patterns; and forming the second spacer patterns on the exposed sidewall of the first spacer patterns. These methods may further include removing the polished mold layers. In other embodiments of the invention, the polished mold layer may be removed after the second spacer patterns are formed.

In yet other embodiments, a plurality of support patterns may be formed on the etch-target layer. In still other embodiments, the support patterns formed on the etch-target layer may be spaced apart from one another in one direction. A width of each support pattern in the one direction may be substantially equal to a distance between a pair of adjacent support patterns. In other embodiments of the invention, a width of a lower surface of the first spacer patterns may be substantially equal to that of a lower surface of the second spacer patterns. In some embodiments of the invention, the support patterns may have an etch selectivity with respect to the first spacer patterns and the second spacer patterns.

In still other embodiments of the invention, the forming of the second spacer patterns and the removing of the support patterns may include forming conformally a second spacer layer on the substrate having the support patterns and the first spacer patterns; carrying out an anisotropic etching of the second spacer layer until the support patterns are exposed; and removing the exposed support patterns.

Other embodiments of the invention provide methods of etching a layer. These methods comprise forming a pattern on the layer, forming first spacers on sidewalls of the pattern, forming second spacers on sidewalls of the first spacers, removing the pattern and etching a layer using the first and second spacers as an etch mask. The layer may be formed on a microelectronic substrate. Moreover, the second spacers may be formed directly on the sidewalls of the first spacers.

In some embodiments, the first spacers include a straight (planar) sidewall and a curved (nonplanar) sidewall, and the second spacers are formed on the straight sidewalls of the first spacers. In these embodiments, the pattern may be removed after forming the first spacers on sidewalls of the pattern and before forming the second spacers on the straight sidewalls of the first spacers. Moreover, before forming the second spacers on the straight sidewalls of the first spacers, a second pattern may be formed on the curved sidewalls of the first spacers.

In other embodiments, the second spacers are formed on the curved sidewalls of the first spacers. In these embodiments, the pattern may be removed after both the first and second spacers are formed.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention. In the drawings:

FIGS. 1 to 8 are cross-sectional views for illustrating methods of forming fine patterns according to exemplary embodiments of the present invention; and

FIGS. 9 to 11 are cross-sectional views for illustrating methods of forming fine patterns according to other exemplary embodiments of the present invention.

### DETAILED DESCRIPTION

Methods of forming fine patterns according to exemplary embodiments of the present invention will be described below in more detail with reference to the accompanying drawings. The following exemplary embodiments of the invention are provided so that this disclosure will be thorough and complete, and will fully convey the scope of the invention to those skilled in the art, and the invention should not be constructed as limited to the embodiments set forth herein. Rather, these embodiments of the invention may be embodied in many different forms without departing from the scope and spirit of the invention. As used herein, the term “and/or” includes any and all combinations of one or more of the associated listed items. It will be understood that when an element is referred to as being “on” another element (or variations thereof), it may be directly on the other element or intervening elements may be present. In contrast, when an element is referred to as being “directly on” another element (or variations thereof), there are no intervening elements present. It will also be understood that, although the terms first, second, third, etc. may be used herein to describe various elements or sections, these terms are only used to distinguish one element or section, thus these elements or sections should not be limited by these terms. In drawings, the thickness and relative thickness of elements may have been exaggerated for clarity.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, can therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

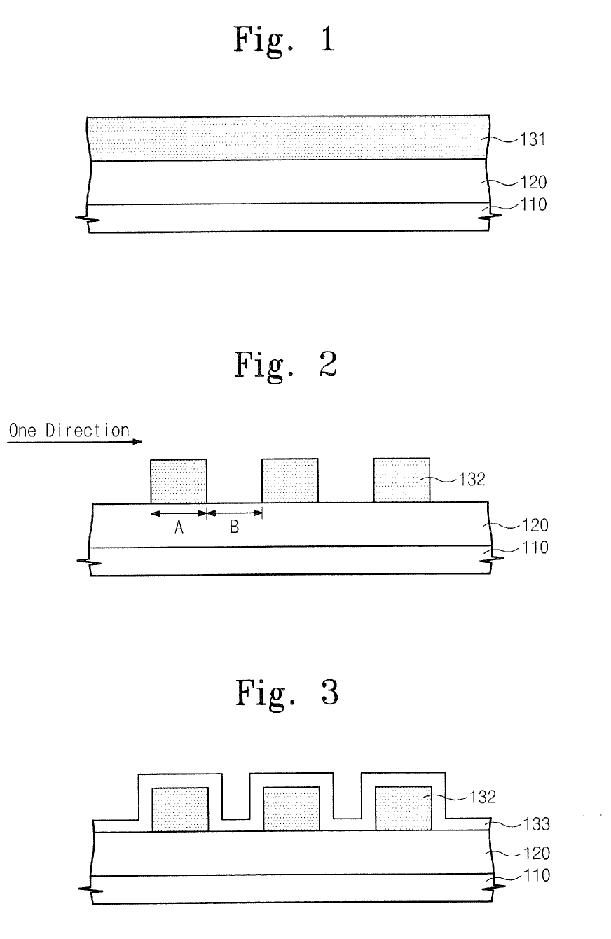

Methods of forming fine patterns according to exemplary embodiments of the present invention will be described with reference to FIGS. 1 to 8.

Referring to FIG. 1, a support layer 131 may be formed on a substrate 110 including an etch-target layer 120, also simply referred to as a layer 120. The substrate 110 may be a semiconductor substrate based on semiconductor elements, but is not limited thereto. Rather, any microelectronic substrate may be used. The etch-target layer 120 may be etched by an etch mask to be formed later. The etch-target layer 120 may include one pattern configuring a semiconductor device. The etch-target layer 120 may contain a conductive substance. For example, the etch-target layer 120 may be a gate layer for forming a gate line and a conductive layer for forming a bit line. In other embodiments, the etch-target layer may be a semiconductor and/or insulating layer. In other embodiments, the etch-target layer 120 may be a part of the semiconductor substrate. The support layer 131 may be formed on the entire surface of the etch-target layer 120. The support layer 131 may contain a substance having an etch selectivity with respect to the etch-target layer 120.

Referring to FIG. 2, the support layer 131 is patterned so that a support pattern 132, also simply referred to as a pattern 132, may then be formed. The support pattern 132 may be formed by a photolithography process. Specifically, the support pattern 132 may be formed by exposing and etching processes after forming a photoresist on the support layer. The width A of the support patterns 132 in one direction may be a minimum line width defined by the photolithography process. However, embodiments of the present invention are not limited thereto. The width A of the support patterns 132 may be larger than the minimum line width defined by the photolithography process.

A plurality of support patterns 132 may be formed on the etch-target layer 120. The plurality of support patterns 132 may be spaced apart from each other in one direction. The distance B between a pair of support patterns 132 adjacent to each other may be a minimum line width defined by the photolithography process. However, the distance B between the pair of support patterns 132 may be larger than the minimum line width defined by the photolithography process. The width A of the support pattern 132 may be substantially equal to the distance B between the pair of support patterns 132. The support patterns 132 may be arranged at substantially regular intervals in one direction. A pitch of the support patterns 132 in one direction may be defined as the sum of the width A and the distance B.

Referring to FIG. 3, a first spacer layer 133 may be formed on the support patterns 132. The first spacer layer 133 may conformally cover the etch-target layer 120 and the support patterns 132. The first spacer layer 133 may contain a substance having an etch selectivity with respect to the etch-target layer 120. The first spacer layer 133 may also have an etch selectivity with respect to the support patterns 132. For example, the first spacer layer 133 may contain a nitride, when the etch-target layer 120 contains at least one of the semiconductor and/or conductive substances, and when the support patterns 132 contain an oxide.

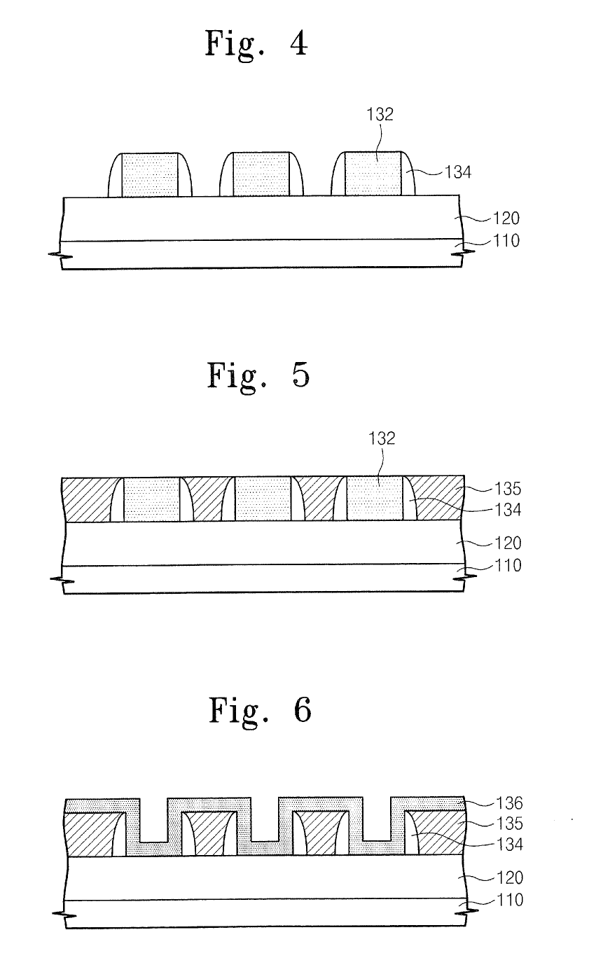

Referring to FIG. 4, the first spacer layer 133 is etched so that first spacer patterns 134, also simply referred to as first spacers 134, may then be formed on sidewalls of the support patterns 132. The sidewalls of the first spacer patterns 134 may come in contact with (i.e., directly on) the sidewalls of the support patterns 132. The first spacer patterns 134 may be formed by an anisotropic etching of the first spacer layer 133. Upper edges of the first spacer patterns 134 may partially be rounded. Thus, the first spacer patterns 134 may have a straight (planar) sidewall and a curved (nonplanar) sidewall. The anisotropic etching may be carried out until a portion of an upper surface of the etch-target layer 120 is exposed.

Referring to FIG. 5, mold patterns 135 may be formed on the etch-target layer 120. The mold patterns 135 may fill up spaces between the first spacer patterns 134. The mold patterns 135 may be formed by polishing a mold layer filling up the space between the first spacer pacers 134. The polishing process may be carried out until the upper surfaces of the support patterns 132 are exposed. The polishing process may include, for example, a chemical mechanical polishing process. In other embodiments, the polishing of the mold patterns 135 may be omitted. The mold patterns 135 may contain a substance having the etch selectivity with respect to the first spacer patterns 134. For example, the mold patterns 135 may contain a PR- or NFC-based substance, when the first spacer patterns 134 contain a nitride. As shown, the mold patterns 135 may be formed on, and extend between, the curved sidewalls of the first spacer patterns 134.

Referring FIG. 6, the support patterns 132 may be removed. The etch-target layer 120 may be exposed between the first spacer patterns 134 by the removal of the support patterns 132. The support patterns 132 may be removed by carrying out an isotropic etching. For example, the support patterns 132 may be removed by the isotropic etching using a wet etchant.

A second spacer layer 136 may be formed on the etch-target layer 120. The second spacer layer 136 may conformally be formed on the mold patterns 135 and the first spacer patterns 134. The second space layer 136 may come in contact with (i.e., may be directly on) the (straight) sidewalls of the first spacer patterns 134, which are exposed by the removal of the support patterns 132. The second spacer layer 136 may contain a substance having an etch selectivity with respect to the etch-target layer 120. In addition, the second spacer layer 136 may have an etch selectivity with respect to the mold patterns 135. The second spacer layer 136 may, for example, be formed of the same substance as the first spacer patterns 134.

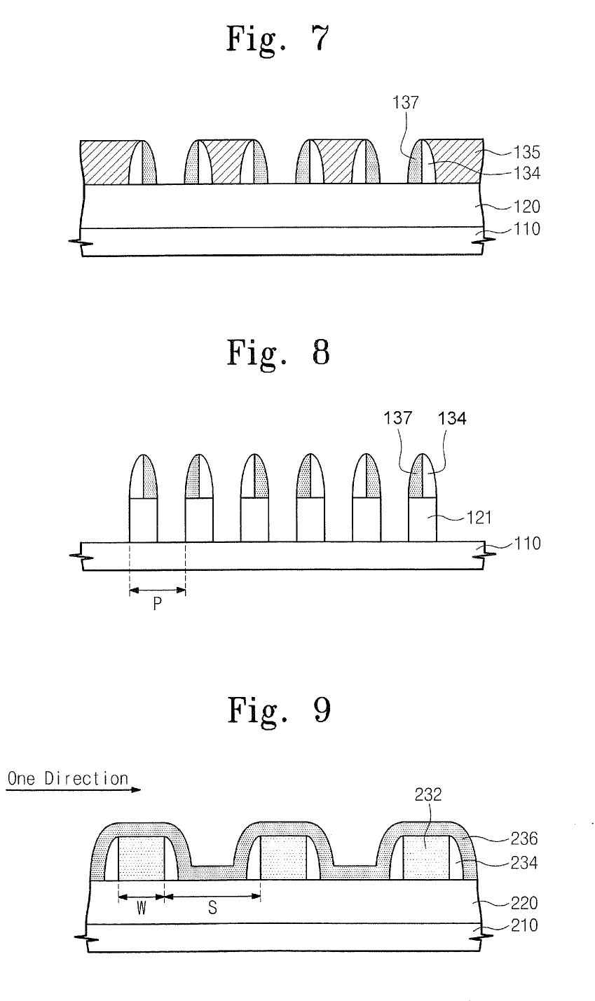

Referring to FIG. 7, second spacer patterns 137, also referred to as second spacers 137, may be formed by removing a portion of the second spacer layer 136. The second spacer patterns 137 may be formed by carrying out the anisotropic etching of the second spacer layer 136. The anisotropic etching may be carried out until a portion of the upper surface of the etch-target layer 120 is exposed. Thus, the etch-target layer 120 may be exposed between the second spacer patterns 137. Lower surfaces of the second spacer patterns 137 may have the substantially same width as those of the first spacer patterns 134. As can be seen in FIG. 7, in some embodiments, the second spacer patterns 137 may also have a straight sidewall and a curved sidewall, and the straight sidewalls of the second spacer patterns may be on, and in some embodiments directly on, the straight sidewalls of the first spacer patterns 134.

Referring to FIG. 8, the mold patterns 135 are removed. The mold patterns 135 may be removed by isotropic etching. The upper surface of the etch-target layer 120 may be exposed by the removal of the mold patterns 135.

The etch-target layer 120 may be patterned by using the first spacer patterns 134 and the second spacer patterns 137 as an etch mask. Subsequently, etched patterns 121 may be formed on the substrate 110. In other words, the layer 120 is etched. The width of the etched pattern 121 may substantially be equal to the sum of the width of the first spacer pattern 134 and the width of the second spacer pattern 137. The pitch P of the etch patterns may be defined by the sum of the width of the etch pattern and the distance between the etch patterns adjacent to each other. The pitch P of the etch patterns may approximately be one half of the pitch (A+B) of the support patterns described with reference to FIG. 2. That is, the etch patterns 121 may be arranged at the pitch P in one direction. As described above, the width A of the support pattern may be a minimum line width defined by the photolithography process. Accordingly, the minimum pitch defined by the photolithography may be the sum of the width A of the support pattern and the distance B between the support patterns as illustrated in FIG. 2. In this case, the pitch P of the etched patterns 121 may be one half of the pitch (A+B) of the support patterns 132.

As a result, the etched patterns 121 may be formed to have the pitch P smaller than a minimum pitch defined by the photolithography process. In other embodiments of the invention, even though the support patterns are formed to have two times of the minimum pitch defined by the photolithography, it can form the patterns to be arranged at a conventional minimum pitch. In any event, expensive equipment for the photolithography, which reduces the pitch of the patterns, may not be essential.

A method of forming fine patterns according to other embodiments of the invention will now be described in connection with reference to FIGS. 9 to 11.

Referring to FIG. 9, a substrate 210 including an etch-target layer 220, also simply referred to as a layer 220, is prepared. The substrate 210 may be a semiconductor substrate based on semiconductor elements, or any other microelectronic substrate. The etch-target layer 220 may form patterns configuring a semiconductor device. The etch-target layer 220 may be a separate layer formed on the substrate 210 or be a part of the substrate 210. The etch-target layer 220 may be conductive, semiconductive and/or insulating.

A plurality of support patterns 232, also simply referred to as patterns 232, may be formed on the etch-target layer 220. The support patterns 232 may be spaced from one another in one direction. After a support layer is formed on the etch-target layer 220, the support patterns 232 may be formed by patterning the support layer. The support patterns 232 may be arranged at regular intervals in one direction. The distance S between a pair of support patterns 232, which are adjacent to each other, may be larger than the width W of the support pattern 232 in one direction.

First spacer patterns 234, also simply referred to as first spacers 234, may be formed on sidewalls of the support patterns 232. The first spacer patterns 234 may contain a substance having an etch selectivity with respect to the etch-target layer 220 and the support patterns 232. As illustrated, the first spacer patterns 234 may have a straight (planar) sidewall and a curved (nonplanar) sidewall.

A second spacer layer 236 may be formed on the support patterns 232 and the first spacer patterns 234. The second spacer layer 236 may conformally be formed on the etch-target layer 220 and the support patterns 232. The second spacer layer 236 may contain a substance having an etch selectivity with respect to the etch-target layer 220. For example, the second spacer layer 236 may contain the same substance as the first spacer patterns 234. Alternatively, the second spacer layer 236 may contain substances different from those of the first spacer patterns 234.

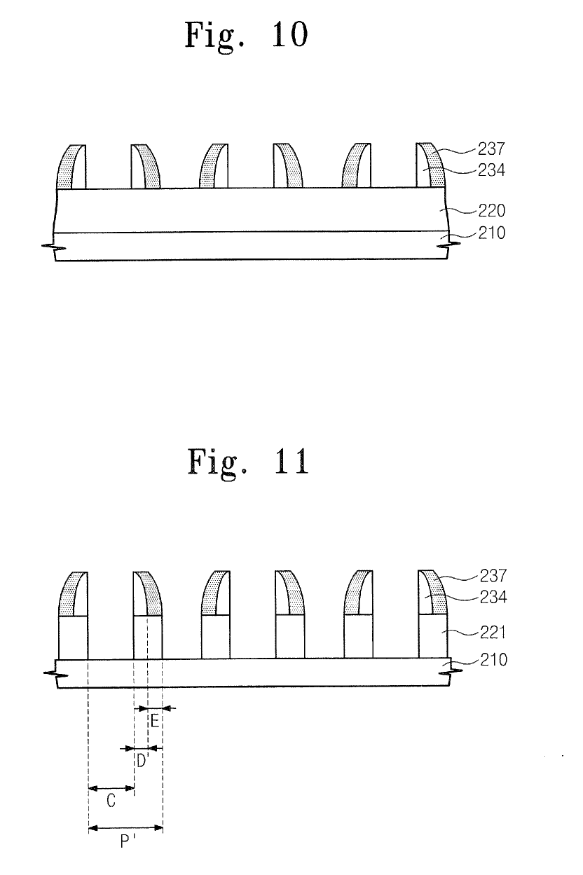

Referring to FIG. 10, second spacer patterns 237, also simply referred as second spacers 237, may be formed by etching the second spacer layer 236. The second spacer patterns 237 may be formed by carrying out anisotropic etching of the second spacer layer 236 until the upper surface of the etch-target layer 220 is exposed. The second spacer patterns 237 may include sidewalls coming in contact with (i.e., directly on) the sidewalls of the first spacer patterns 234. Specifically, the second spacer patterns 237 may include curved sidewalls and may be formed on, and in some embodiments directly on, the curved sidewalls of the first spacer patterns 234. The lower surfaces of the second spacer patterns 237 may have substantially the same width as those of the first spacer patterns 234. The thickness of the second spacer patterns 237 may be controlled such that the sum of the width of the lower surface of the first spacer pattern 234 and the width of the lower surface of the second spacer pattern 237 is equal to the width W of the support pattern. After the second spacer patterns 237 are formed, the support patterns 232 may be removed. The support patterns 232 may be removed by isotropic etching.

After the second spacer patterns 237 are formed, the distance S between the support patterns 232 may be equal to the sum of the width W of the support pattern, twice the width of the lower surface of the first spacer pattern 234, and twice the width of the lower surface of the second spacer pattern 237.

Referring to FIG. 11, the etch-target layer 220 may be patterned by using the first spacer patterns 234 and the second spacer patterns 237 as an etch mask. Etched patterns 221 may be formed on the substrate 210. The width of the etched patterns 221 may substantially be equal to the sum of the width of the lower surface of the first spacer pattern 234 and the width of the lower surface of the second spacer pattern 237. The distances C between the etched patterns 221 may be equal to one another, when the width W of the support patterns 232 is equal to the sum of the width D of the lower surface of the first spacer patterns 234 and the width E of the lower surface of the second spacer patterns 237.

The etched patterns 221 may be arranged to have the distance equal to the width of the support pattern C. The pitch P′ of the etched patterns 221 may substantially be equal to the sum of the width of the support pattern C, the width of the lower surface of the first spacer pattern D, and the width of the lower surface of the second spacer pattern 237 E. The width of the etched pattern 221 may be equal to the distance between the etch patterns C, when the width of the support patterns C is equal to the sum of the width of the lower surface of the first spacer patterns D and the width of the lower surface of the second spacer patterns E.

Since the etched patterns 221 may be formed by using the first spacer patterns 234 and the second spacer patterns 237 as an etch mask, the etch patterns 221 may be formed to have a size far smaller than the patterns formed by the photolithography. In addition, since the distance between the etched patterns 221 may be determined by the thickness of the support patterns 232 and the spacer patterns 234 and 237, the distance between the etched patterns 221 may be adjusted by controlling the thickness of the support patterns 232 and/or the spacer patterns 234 and 237.

Methods of forming fine patterns according to various embodiments of the invention may be applicable to various fields such as electronic equipment and devices configuring the electronic equipment. For example, methods of forming fine patterns according to various embodiments of the invention may be applicable to the formation of a semiconductor device. Specifically, some embodiments of the invention may be applicable to forming a memory device of the semiconductor device. As an example, some embodiments of the invention can be applied to forming patterns of a non-volatile memory device. More specifically, some embodiments of the invention can be applied to forming gate lines of the non-volatile memory device.

According to various embodiments of the invention, finer patterns may be formed.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A method of forming fine patterns, comprising:
forming an etch-target layer on a substrate;
forming support patterns on the etch-target layer;
forming first spacer patterns on sidewalls of the support patterns;
forming second spacer patterns coming in contact with the first spacer patterns;
removing the support patterns; and
etching the etch-target layer by using the first spacer patterns and the second spacer patterns as an etch mask.

2. The method of forming fine patterns of claim 1, wherein the forming of the second spacer patterns and the removing of the support patterns include:
forming a mold layer on the substrate having the support patterns and the first spacer patterns;
exposing one sidewall of the first spacer patterns by removing the support patterns; and
forming the second spacer patterns on the exposed one sidewall of the first spacer patterns.

3. The method of forming fine patterns of claim 2, further comprising polishing the mold layer,
wherein the polishing of the mold layer exposes upper surfaces of the support patterns.

4. The method of forming fine patterns of claim 2, wherein:
a plurality of support patterns are formed on the etch-target layer,
the support patterns are spaced apart from one another on the etch-target layer in one direction, and
a width of each support pattern in the one direction is equal to a distance between a pair of adjacent support patterns.

5. The method of forming fine patterns of claim 2, further comprising removing the mold layer before etching the etch-target layer.

6. The method of forming fine patterns of claim 5, wherein the mold layer is removed after the second spacer patterns are formed.

7. The method of forming fine patterns of claim 1, wherein the support patterns and the mold layer contain a substance each having an etch selectivity with respect to the first spacer patterns and the second spacer patterns.

8. The method of forming fine patterns of claim 1, wherein a width of a lower surface of the first spacer patterns is equal to that of a lower surface of the second spacer patterns.

9. The method of forming fine patterns of claim 1, wherein the forming of the second spacer patterns and the removing of the support patterns include:
forming conformally a second spacer layer on the substrate having the support patterns and the first spacer patterns;
forming the second spacer patterns by performing an anisotropic etching of the second spacer layer until the support patterns are exposed; and
removing the exposed support patterns.

10. The method of forming fine patterns of claim 9, wherein:
a plurality of support patterns are foamed on the etch-target layer,
the support patterns are spaced apart from one another in one direction, and
a distance between a pair of adjacent support patterns is equal to a sum of the width of the support pattern in the one direction, twice the width of the first spacer pattern in the one direction, and twice the width of the second spacer pattern in the one direction.

11. A method of etching a layer, comprising:
forming a pattern on the layer;
forming first spacers on sidewalls of the pattern;
forming second spacers on sidewalls of the first spacers;
removing the pattern; and
etching the layer using the first and second spacers as an etch mask.

12. The method of claim 11:
wherein the first spacers include a straight sidewall and a curved sidewall; and
wherein the forming second spacers on sidewalls of the first spacers comprises forming the second spacers on the straight sidewalls of the first spacers.

13. The method of claim 11:
wherein the first spacers include a straight sidewall and a curved sidewall; and
wherein the forming second spacers on sidewalls of the first spacers comprises forming the second spacers on the curved sidewalls of the first spacers.

14. The method of claim 12 wherein the removing the pattern is performed between the forming first spacers on sidewalls of the pattern and the forming second spacers on the straight sidewalls of the first spacers.

15. The method of claim 13 wherein the removing the pattern is performed after the forming first spacers on sidewalls of the pattern and the forming second spacers on the curved sidewalls of the first spacers.

16. The method of claim 11 wherein the forming a pattern on the layer is preceded by forming the layer on a microelectronic substrate.

17. The method of claim 12 wherein the forming second spacers on the straight sidewalls of the first spacers comprises forming the second spacers directly on the straight sidewalls of the first spacers.

18. The method of claim 13 wherein the forming second spacers on the curved sidewalls of the first spacers comprises forming the second spacers directly on the curved sidewalls of the first spacers.

19. The method of claim 11 wherein the layer is on a microelectronic substrate.

20. The method of claim 14 wherein the pattern is a first pattern and wherein the following is performed before the forming second spacers on the straight sidewalls of the first spacers:
forming a second pattern between the curved sidewalls of the first spacers.
